(19) United States
(12) Patent Application Publication
(10) Pub. No.: US 2020/0058539 A1
(43) Pub. Date: Feb. 20, 2020

(54) COATING MATERIAL FOR PROCESSING CHAMBERS

(71) Applicant: Applied Materials, Inc., Santa Clara, CA (US)

(72) Inventors: Sudha RATHI, San Jose, CA (US); Dong Hyung LEE, Danville, CA (US); Abdul Aziz KHAJA, San Jose, CA (US); Ganesh BALASUBRAMANIAN, Fremont, CA (US); Juan Carlos ROCHA, San Carlos, CA (US)

(21) Appl. No.: 16/520,166

(22) Filed: Jul. 23, 2019

Related U.S. Application Data
(60) Provisional application No. 62/719,575, filed on Aug. 17, 2018.

(51) Int. Cl. H01L 21/687; H01L 21/683; C23C 16/458; C23C 16/46; C23C 16/50; C23C 16/40

(52) U.S. Cl. CPC H01L 21/68757; H01L 21/68735; H01L 21/6833; C23C 16/401; C23C 16/46; C23C 16/50; C23C 16/4586

(57) ABSTRACT

Embodiments described herein relate to coating materials with high resistivity for use in processing chambers. To counteract the high charges near the top surface of the thermal conductive support, the top surface of the thermal conductive support can be coated with a high resistivity layer. The high resistivity of the layer reduces the amount of charge at the top surface of the thermally conductive element, greatly reducing or preventing arcing incidents along with reducing electrostatic chucking degradation. The high resistivity layer can also be applied to other chamber components. Embodiments described herein also relate to methods for fabricating a chamber component for use in a processing environment. The component can be fabricated by forming a body of a chamber component, optionally ex-situ seasoning the body, installing the chamber component into a processing chamber, in-situ seasoning the chamber component, and performing a deposition process in the processing chamber.

### CROSS-REFERENCE TO RELATED APPLICATIONS

This application claims priority to U.S. Provisional Patent Application No. 62/719,575, filed Aug. 17, 2018, which is herein incorporated by reference in its entirety.

### BACKGROUND

### Field

Embodiments described herein generally relate to coating materials for use in processing chambers and, more particularly, to coating materials having a high electrical resistivity for use in processing chambers.

### Description of the Related Art

Semiconductor processing apparatuses typically include a process chamber that is adapted to perform various deposition, etching, or thermal processing steps on a wafer, or substrate, that is supported within a processing region of the process chamber. Gases are provided in a processing region of the process chamber. The gases become “excited” by the delivery of RF energy, transitioning the gases into a plasma state, thereafter forming a layer on the surface of the wafer. Typically, the wafer is supported by a wafer support that is disposed in the processing region of the processing chamber. The wafer support, hereinafter called a thermal conductive support, can also act as a heater. The thermal conductive support generates heat by use of an electrode embedded within its body in which alternating current (AC) power is provided to.

When processing larger wafers, larger processing chambers are needed. The larger the processing chambers, the more power is needed to “excite” the gas within the processing region to its plasma state, creating a higher electric potential within the processing region. Additionally, thermal conductive supports are typically made of material that has leakage current paths that allow leakage currents to form. The leakage current causes charge to flow to and form a charged region at the top surface of the thermal conductive support. The charges then build up near the top surface of the thermal conductive support, and at a greater amount when higher temperatures are used during processing, creating a higher concentrated electric field near the top surface of the thermal conductive support.

As higher charges are created at the top surface of the thermal conductive support, it exposes the thermal conductive support to more electrical arcing incidents. The arcing is caused by the higher concentrated electric field near the top surface of the thermal conductive support inducing a large discharge current, causing an arc to form from one or more surfaces of the thermal conductive support. These arcing incidents can also occur on the surfaces of the chamber walls, the process kit stacks, and/or other chamber components during processing. Arcing events result in particle contamination, wafer scrap, yield loss, and chamber downtime. Additionally, when direct current (DC) voltage is applied to the thermal conductive support for electrostatic chucking, the leakage current in the thermal conductive support causes charges generated by the DC voltage to leak out of the thermal conductive support during plasma processing. This results in an unstable chucking performance leading to chucking degradation.

Accordingly, there is a need in the art to prevent arcing and electrostatic chucking degradation incidents by reducing the charge at the top surface of the thermal conductive support and at the surfaces of other chamber components.

### SUMMARY

One or more embodiments described herein generally relate to coating materials with high electrical resistivity for use in substrate processing chambers.

In one embodiment, a process chamber component includes a dielectric body having a first surface; an electrode that is disposed within the dielectric body; and a high resistivity layer, wherein the high resistivity layer is disposed on the first surface of the dielectric body, wherein the high resistivity layer has an electrical resistivity between about 1×10⁹ and about 1×10¹⁷ ohm-centimeters.

In another embodiment, a processing chamber includes a process kit stack having an inner surface, wherein the inner surface faces a processing region within a chamber body; a thermal conductive support, wherein the thermal conductive support comprises: a dielectric body with a top surface, wherein the top surface supports a substrate; an electrode that is disposed within the dielectric body; and a high resistivity layer, wherein the high resistivity layer is disposed on the inner surface of the at least one process kit and on the top surface of the dielectric body, wherein the high resistivity layer has an electrical resistivity between 1×10⁹ and 1×10¹⁷ ohm centimeters.

One or more embodiments described herein also generally relate to methods for fabricating a chamber component for use in a processing environment.

In one embodiment, a method for fabricating a chamber component for use in a processing environment includes forming a body of the chamber component; installing the chamber component into a processing chamber; depositing a high resistivity layer on the surface of the body in-situ, wherein a pressure between about 50 mTorr and about 20 Torr is applied, a power between about 10 and about 3000 watts is applied, a temperature is between about 50 and about 1100 degrees Celsius, a silicon-containing gas is applied at a gas flow rate between about 2 to about 20000 sccm, an oxygen containing gas is applied at a gas flow rate between about 2 sccm to about 30000 sccm, and inert gases are applied at a flow rate between about 10 sccm to about 20000 sccm; and performing a deposition process in the processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a side cross-sectional view of a processing chamber in the prior art;

FIG. 2A is a side cross-sectional view of a processing chamber according to at least one embodiment described herein;

FIG. 2B a close up sectional view of a portion of the processing chamber in FIG. 2A; and

FIG. 3 is a flow chart of a method for fabricating a chamber component according to at least one embodiment described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, numerous specific details are set forth to provide a more thorough understanding of the embodiments of the present disclosure. However, it will be apparent to one of skill in the art that one or more of the embodiments of the present disclosure may be practiced without one or more of these specific details. In other instances, well-known features have not been described in order to avoid obscuring one or more of the embodiments of the present disclosure.

Embodiments described herein generally relate to process chamber components that include a coating that has a high electrical resistivity for use in plasma processing. As higher temperature and higher plasma density processes are developed for processing semiconductor substrates, higher amounts of charge can be created and trapped with the various exposed processing chamber components, such as at the top surface of a thermal conductive support disposed within a processing region of the process chamber. The generated and trapped charges will expose the thermally conductive support to more frequent arcing incidents. Arcing events result in particle contamination, wafer scrap, yield loss, and tool downtime. To counteract the higher amounts of charge that are trapped near the top surface of these process chamber components, such as a thermal conductive support, the top surface of the thermal conductive support can be coated with a high resistivity layer. The high electrical resistivity of the formed layer acts to increase the impedance formed between the process chamber component (e.g., thermal conductive support), plasma and ground within a processing region of the processing chamber during normal processing, thus reducing the ability of the trapped charge to form an arc between the chamber component and ground.

Overall, embodiments described herein will greatly reduce or prevent arcing incidents, which will lead to less tool downtime and greater processing efficiency. As will be described further below, the high resistivity of the coating will also help prevent electrostatic chucking degradation. Additionally, after the high resistivity layer is applied once using the methods disclosed herein, it has been found that greater than 2,000 wafers, such as between 4,000 and 10,000 wafers, can be processed without the need to remove the thermal conductive support. In conventional approaches, the only way to recover the process after an arcing incident is to replace the thermal conductive element, which greatly decreases the chamber uptime and increases the cost of operation. As will be discussed below, the high resistivity layer can also be applied to other chamber components, helping prevent arcing incidents in those components as well.

Embodiments described herein also generally relate to methods for fabricating a chamber component for use in a processing environment. The chamber component can be fabricated by forming a body of the chamber component, optionally ex-situ seasoning the body, installing the chamber component into a processing chamber, in-situ seasoning the chamber component, and performing a plurality of substrate deposition processes in the processing chamber.

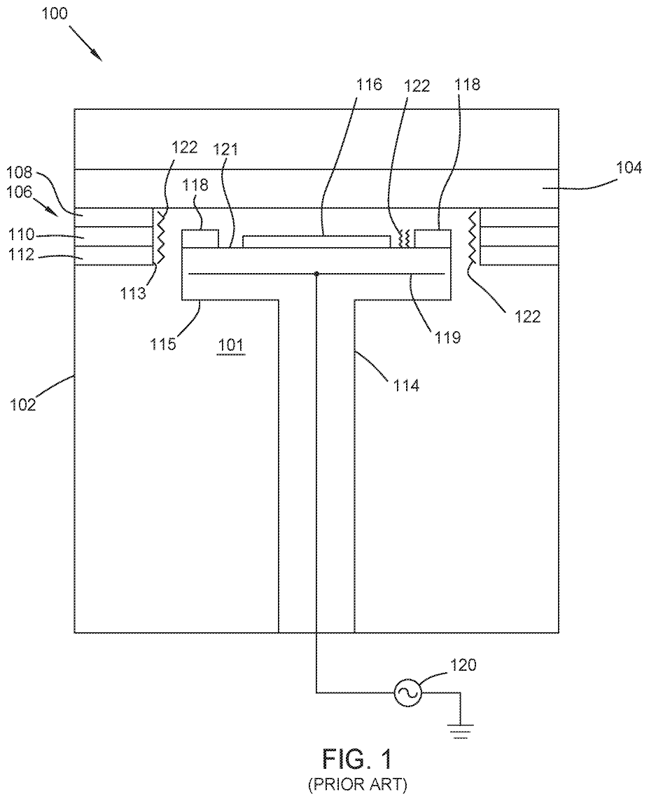

FIG. 1 shows a side cross-sectional view of a processing chamber 100 in the prior art. By way of example, embodiments of the processing chamber 100 and 200 (discussed below) are described in terms of a plasma deposition chamber, but any other type of wafer processing chamber may be used without deviating from the basic scope of the disclosure herein. The processing chamber 100 includes chamber sidewalls 102 that enclose a processing region 101, a faceplate 104, at least one process kit stack 106, and a thermal conductive support 114. The faceplate 104 may be flat as shown and include a plurality of through-channels (not shown) used to uniformly distribute process gases into the processing region 101 in which the substrate 116 is disposed.

The at least one process kit stack 106 includes a top dielectric spacer 108, a side electrode 110, and a bottom dielectric spacer 112. A gas inlet channel and a gas outlet channel (not shown) may be formed in the top dielectric spacer 108, side electrode 110, and/or a bottom dielectric spacer 112. An inner surface 113 of the at least one process kit stack 106 faces the processing region 101. The thermal conductive support 114 is generally a substrate supporting element that may include a pedestal heater used for wafer processing. The pedestal heater may be formed from a dielectric material, such as a ceramic material (e.g., AlN, BN, or Al₂O₃ material). The chamber sidewalls 102 may comprise an electrically conductive and thermally conductive material, such as aluminum or stainless steel.

A substrate 116 sits on a top surface 121 of a body 115 of the thermal conductive support 114. An edge ring 118 is also coupled to the top surface 121 of the thermal conductive support 114. An outer edge of the edge ring 118 may align with an outer edge of the thermal conductive support 114. An electrode 119 is embedded within the body 115 of the thermal conductive support 114, and is powered by a power source 120. In some embodiments, the power source 120 may provide a direct current (DC) voltage of −980 volts (V) to the electrode 119, although other voltages can also be applied. The power generated from the power source can operate at a desired frequency. The power generated by the power source 120 acts to energize (or “excite”) the gases in the processing region 101 into a plasma state to, for example, form a layer on the surface of the substrate 116 during a plasma deposition process.

The power provided to the electrode 119 can help “bias” the substrate 116. The electrode 119 can also act as an electrostatic chucking electrode, helping to provide a proper holding force to the substrate 116 against the top surface 121 of the thermal conductive support 114 by use of a separate high voltage power supply (not shown) that is electrically coupled to the electrode 119.

In prior art embodiments, such as illustrated in FIG. 1, the top surface 121 of the thermal conductive support 114 is exposed to the processing region 101. When processing a larger sized substrate 116, a larger processing chamber 100 is needed. The larger the processing chamber 100, the more power is needed to “excite” the process gases disposed within the processing region 101 to its plasma state. Additionally, the thermal conductive support 114 can be made of material that has current leakage paths that create a large leakage current. The leakage current causes charge to flow to the top surface 121 of the thermal conductive support 114. The charges then build up near the top surface 121 of the thermal conductive support 114 at higher temperatures during processing, creating a higher concentrated electric field near the top surface 121 of the thermal conductive support 114.

As a larger amount of charge is formed or trapped at the top surface 121 of the thermal conductive support 114, the chance of generating an arc are greatly increased. The large amount of trapped charge generates a higher concentrated electric field between the top surface 121 of the thermal conductive support 114 and ground which eventually induces a discharge current, in the form of an arc to be generated. Examples of where arcing incidents can occur are shown by reference number 122. As shown, arcing incidents can occur on the top surface 121 of the thermal conductive support 114 and on the inner surface 113 of the at least one portion of the process kit stack 106. These arcing incidents can also occur on the surfaces of the chamber sidewalls 102, and/or on other chamber components during processing. As noted above, arcing events can result in particle contamination, wafer scrap, yield loss, and tool downtime.

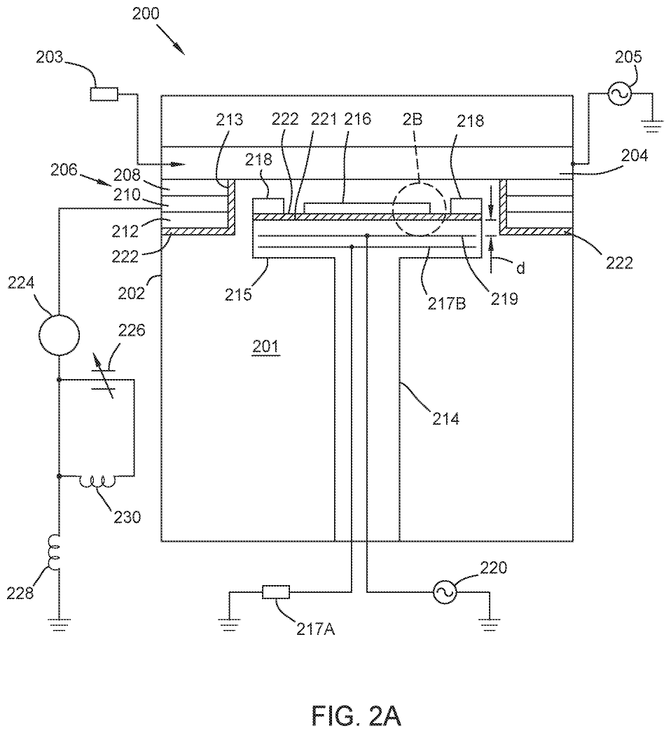

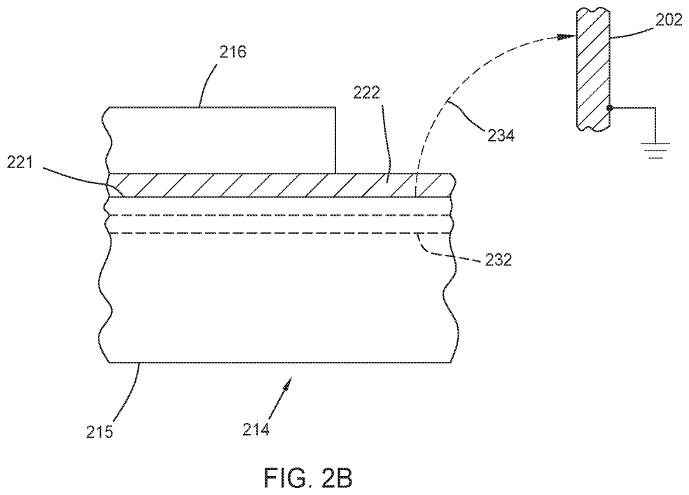

FIG. 2A shows a side cross-sectional view of a processing chamber 200 according to at least one embodiment described herein. Embodiments described herein are designed to greatly reduce or eliminate the arcing events that occur in the prior art, as shown for example by reference number 122 in FIG. 1. The processing chamber 200 includes chamber sidewalls 202 that enclose a processing region 201, a faceplate 204, at least one process kit stack 206, and a thermal conductive support 214. The faceplate 204 may be flat as shown and include a plurality of through-channels (not shown) used to distribute process gases into the processing region 201. The processing gases are supplied by a gas supply 203. A power source 205 acts to power the faceplate 204, and energizes (or “excites”) the gases in the processing region 201 into a plasma state to, for example, form a layer on the surface of the substrate 216 during a plasma deposition process.

The process kit stack 206 includes a top dielectric spacer 208, a side electrode 210, and a bottom dielectric spacer 212. The top dielectric spacer 208 and bottom dielectric spacer 212 act to isolate the side electrode 210 from the body of the processing chamber 200. The dielectric spacers 208 and 212 can be made of a ceramic material. The side electrode 210 can be made from a conductive material, such as aluminum. The side electrode 210 is electrically coupled to a variable capacitor 226, and terminated to ground through a first inductor 228. A second inductor 230 is electrically coupled in parallel to the variable capacitor 226 to provide a path for low frequency RF to ground. In addition, a sensor 224 is positioned between the side electrode 210 and the variable capacitor 226 for use in controlling the current flow through the side electrode 210 and the variable capacitor 226. A gas inlet channel and a gas outlet channel (not shown) may be formed in the top dielectric spacer 208, side electrode 210, and/or a bottom dielectric spacer 212. An inner surface 213 of the at least one process kit stack 206 faces the processing region 201. The thermal conductive support 214 is generally a substrate supporting element that may include a pedestal heater used for substrate processing. The pedestal heater may be formed from a dielectric material, such as a ceramic material (e.g., AlN, BN, or Al₂O₃ material) and includes a heating element 217B that is powered by an AC heater power supply 217A. The chamber sidewalls 202 may comprise an electrically conductive and thermally conductive material, such as aluminum or stainless steel.

A substrate 216 sits on a top surface 221 of a body 215 of the thermal conductive support 214. An edge ring 218 is also coupled to the top surface 221 of the thermal conductive support 214. An outer edge of the edge ring 218 may align with an outer edge of the thermal conductive support 214. An electrode 219 is embedded within the body 215 of the thermal conductive support 214, and is powered by a power source 220. In some embodiments, the power source 220 may provide a direct current (DC) voltage of −980 volts (V) to the electrode 219, although other voltages can also be applied. In some embodiments, the power generated from the power source 220 can operate at frequencies between about 200 kHz and about 81 MHz, more commonly between about 13.56 MHz and about 40 MHz. However, the power source 220 can operate at other frequencies.

The power provided to the electrode 219 can help “bias” the substrate 216. The electrode 219 can also act as an electrostatic chucking electrode, helping to provide a proper holding force to the substrate 216 against the top surface 221 of the thermal conductive support 214 by use of a separate high voltage power supply (not shown) that is electrically coupled to the electrode 219. The electrode 219 can be made of a refractory metal, such as molybdenum (Mo), tungsten (W), or other similar materials. The electrode 219 is embedded at a distance (referenced as “d” in FIG. 2A) from the top surface 221 of the thermal conductive support 214. In some embodiments, the distance is at least 1 millimeter, but can be other distances from the top surface 221. In processing applications that use a high amount of RF power, which is generated by the power source 220, there is a large amount of voltage generated between the electrode 219 and ground when the plasma is generated within the processing region 201. The higher voltage leads to a higher amount of charge at the top surface 221 of the thermal conductive support 214.

To help counteract the charges trapped near the top surface 221 of the thermal conductive support 214, the top surface 221 of the thermal conductive support 214 is coated with a high resistivity layer 222. Additionally, other conductive components facing the processing region 201, such as the inner surface 213 of the at least one process kit stack 206, can also be coated with the high resistivity layer 222, as shown in FIG. 2A. The high resistivity of the layer acts to trap the charge at the surface of or inside the high resistivity layer 222, acting to reduce the charge at the top surface 221 of the thermally conductive support 214. As illustrated in FIG. 2B, which shows a close up sectional view of a portion of the processing chamber 200 in FIG. 2A, a path 234 of current between the plasma and ground flows into the body 215 of the thermal conductive support 214. During processing, a greater current flows along the path 234, causing charges 232 to build near the top surface 221 of the body 215. However, the high resistivity layer 222 acts to block charges generated in the plasma from becoming trapped at the top surface 221, reducing the amount of charges 232 near the top surface 221 of the body 215, and/or block charges trapped at the top surface 221 from arcing to a chamber ground. The reduction of amount of trapped charge and/or added impedance to ground will eliminate or greatly reduce the number of arcing events.

Additionally, the high resistivity layer 222 acts to reduce electrostatic chucking degradation, improving electrostatic chucking performance. Normally, when DC voltage is applied from a power source to an electrode disposed within the thermal conductive support for electrostatic chucking, the leakage current in the thermal conductive support causes charges generated by the DC voltage to leak out of the thermal conductive support during plasma processing. However, the high resistivity layer 222, as described in embodiments herein, helps counteract the charges from leaking out of the thermal conductive support 214. In other words, the high resistivity layer 222 acts to “block” the charges generated by the DC voltage applied from the power source 220 to the electrode 219 from leaking to ground. This is partly due the electrical properties of the high resistivity layer 222 material, including the electrical resistivity and dielectric constant. In some embodiments, the dielectric constant of the high resistivity layer 222 material can be between 3.4 and 4.0, which can be more than two times less than the dielectric constant of the thermal conductive support 214 material. Furthermore, in some embodiments, the electrical resistivity of the high resistivity layer 222 material can be between 1×10⁹ and about 1×10¹⁷ ohm-centimeters, which can be more than six orders of magnitude higher than the electrical resistivity of the thermal conductive support 214 material. Overall, the electrical properties of the high resistivity layer 222 act to stabilize the chucking performance, preventing degradation over time.

In some embodiments of the disclosure, after the high resistivity layer 222 is applied once to a chamber component (e.g., conductive support), greater than 2,000 substrates (or wafers), such as between 4,000 and 10,000 substrates (or wafers), can be processed without the need to remove the thermal conductive support 214 due to damage created by the arc, and in some cases the reapplication of the high resistivity layer 222. With other approaches, the only way to recover the process is to regularly change the process kit component (e.g., thermal conductive element) which greatly decreases the chamber uptime and increases the cost of operation. In at least one embodiment, the high resistivity layer 222 is applied between the top surface 221 and a bottom surface of the edge ring 218, which is disposed around the edge of the thermal conductive support 214. In other embodiments using ex-situ layer formation processes, the top surface 221 of the thermal conductive support 214 can be coated with the high resistivity layer 222 without the edge ring 218.

As discussed above, the high resistivity layer 222 will have a high electrical resistivity. The high resistivity layer 222 can have an electrical resistivity between about 1×10⁹ and about 1×10¹⁷ ohm-centimeters. In some embodiments, the electrical resistivity of the high resistivity layer 222 is approximately 1×10¹³ ohm-centimeters. Other properties of the high resistivity layer 222 can also help prevent arcing incidents. For example, the high resistivity layer 222 can have a dielectric thickness between about 1 and about 20 micrometers. Dielectric thicknesses within this range can act to trap more charge inside the high resistivity layer 222, acting to prevent charges from building up near the top surface 221 of the thermal conductive support 214. The high resistivity layer 222 can also have a dielectric constant between about 3 and about 10. In some embodiments, the dielectric constant can be between about 3.4 to about 4.0. Dielectric constants within this range can also act to prevent charge buildup at the top surface 221 due to the increased impedance between the surface of the chamber component (e.g., top surface 221) to ground. The high resistivity layer 222 can be made of silicon oxide (SiOₓ), or other similar materials with material properties similar to those discussed above.

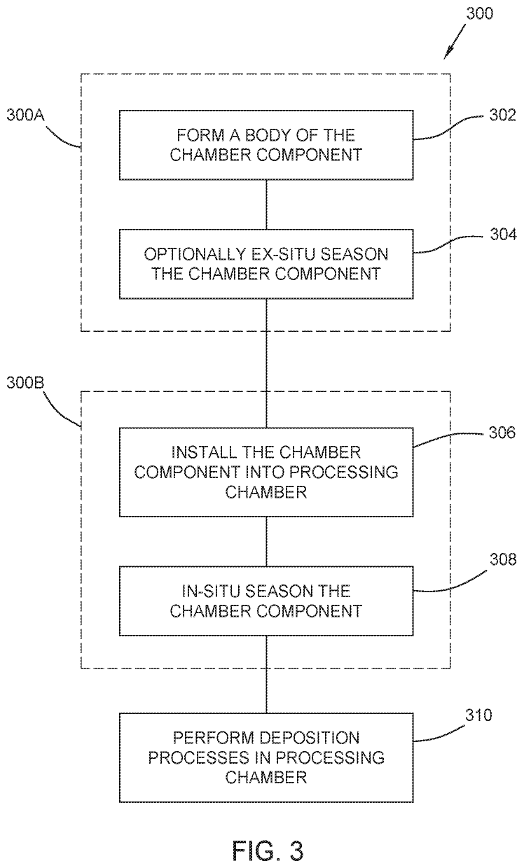

Additionally, in some embodiments, the high resistivity layer 222 is disposed over one or more surfaces of the thermal conductive support 214 to prevent the surfaces of the thermal conductive support 214 from being attacked or eroded by the processing chemistry used during one or more of the deposition or cleaning processes performed in the substrate processing chamber. In one example, the high resistivity layer 222 is formed from a material that is not significantly attacked or eroded during an in-situ cleaning process performed in the substrate processing chamber. Typically, in-situ cleaning processes may include the use of one or more halogen containing gases, such as chlorine (CI) or fluorine (F), that are excited into a plasma state by the plasma generation components in the processing chamber. If the high resistivity layer 222 is attacked or eroded to a point where the damaged layer affects the ability of an electrostatic chuck version of the thermal conductive support 214 to “chuck” and/or support a substrate, a new coating can be formed over the surfaces of the thermal conductive support 214 to allow the thermal conductive support 214 to function as the thermal conductive support 214 did when the coating was newly formed over surfaces thereof. A process of forming the high resistivity layer 222 is described further below in conjunction with FIG. 3.

In some embodiments, the high resistivity layer 222 also includes mechanical properties that minimize the amount of abrasion of the surface of the high resistivity layer 222 due to the repetitive clamping or electrostatic chucking of a semiconductor substrate thereon. Typically, semiconductor substrates have a rough backside surface that can abrade the surface of a thermal conductive support 214 due to the repetitive exposure to multiple substrates which are processed in the substrate processing chamber. In one non-limiting example, the surface of the high resistivity layer 222 has a hardness that is substantially equal to or greater than the hardness of the surface of the thermal conductive support 214. In another example, the surface of the high resistivity layer 222 has a hardness that is substantially equal to or greater than the hardness of a semiconductor substrate (e.g., substrates containing Si, GaN or sapphire). In one example, the surface hardness is between about 103 and about 104 MPa. Therefore, as described above, in some embodiments, the material of the high resistivity layer 222 can be used to stabilize the electrostatic chucking process, due to superior electrical properties of the high resistivity layer 222, and also protect the surface of the thermal conductive support 214 from chemical attack and mechanical abrasion.

FIG. 3 shows a flow chart of a method 300 for fabricating a chamber component according to at least one embodiment described herein. Some chamber components fabricated can include the thermal conductive support 214 and/or one or more components within the process kit stack 206 discussed above, although other chamber components can also be fabricated using this method. The method 300 includes manufacturing operations 300A and seasoning operations 300B.

The manufacturing operations 300A include blocks 302 and 304. In block 302, a body of the chamber component is formed. The body can be formed out of metal (e.g., aluminum or SST), a ceramic material (e.g., alumina (Al₂O₃), aluminum nitride (AlN), boron nitride (BN)), or other similar materials. Shortly after formation, the body of the chamber component may be polished to reduce surface imperfections which lead to cracking or particle generation during use. The body may be polished using any suitable electropolishing or mechanical polishing method or process.

Block 304 provides an optional operation of providing a seasoning layer, which includes the high resistivity layer 222, to the chamber component ex-situ. “Ex-situ” seasoning in this disclosure refers to the seasoning of a component in a nonproduction seasoning chamber or anywhere outside of a processing chamber in which the component is used to process a substrate. A seasoning recipe may include a process of exposing a component to one or more plasmas containing a particular chemical composition, in one or more sequences, orders, and/or combinations for one or more time periods. One of the benefits of ex-situ seasoning process may be to reduce or eliminate the need for in-situ seasoning (discussed in block 308). This can decrease the cost of operation of the facility. Additionally, in ex-situ seasoning, because the body of the chamber component can be seasoned without being installed in the processing chamber, the entire body of the chamber component can be coated without other chamber components obstructing or altering the seasoning layer formation process. For example, in one embodiment, the top surface 221 of the thermal conductive support 214 can be coated with the high resistivity layer 222 without the edge ring 218.

The seasoning operations 300B include blocks 306 and 308. In block 306, the chamber component is installed into the processing chamber. Once the component has been installed in the processing chamber, block 308 provides a seasoning layer, which includes the high resistivity layer 222, to the chamber component in-situ. “In-situ” in this disclosure refers to the seasoning of a component inside the processing chamber in which the component is used to process a substrate. The seasoning material forms at least one sealing layer, which comprises the high resistivity layer 222, on the internal surfaces of the chamber and the chamber components, such as on the inner surfaces 213 of the at least one process kit stack 206 and on the top surface 221 of the thermal conductive support 214. The seasoning process can operate at temperatures between about 50 and about 1100 Celsius and at pressures about 50 mTorr to about 20 Torr, for example. It can also operate at RF powers provided to the faceplate 204 by an RF power source 205 or electrode 219 in the thermal conductive support 214 at levels of between about 10 watts and about 3000 watts, for example.

The seasoning process performed in operations 300A and/or 300B may be performed by introducing gases provided from a gas supply 203 through the gas inlet manifold formed within the faceplate 204. In one example, the seasoning layer is a silicon oxide layer which may be deposited by reacting a silicon-containing gas with an oxygen containing gas in the processing chamber. The silicon-containing gas can contain precursor gases such as silane, disilane, and tetraethyl orthosilicate (TEOS). The oxygen containing gas can contain oxygen, carbon dioxide, nitrous oxide, or other amounts of nitrogen and oxygen (NxOy). Other precursor gases such as amounts of carbon, hydrogen, and fluoride (CxHyFz) as well as inert gases such as argon, xenon, and helium, can be introduced into the processing chamber during the seasoning process. During the deposition of the seasoning layer, the silicon-containing gases may be introduced into the processing chamber at a flow rate of between about 2 standard cubic centimeters per minute (sccm) to about 20000 sccm. The oxygen containing gases can be introduced into the processing chamber at a flow rate of between about 2 sccm to about 30000 sccm. Argon, xenon, and helium can be introduced into the processing chamber at a flow rate of between about 10 sccm to about 20000 sccm. CxFy and CxHyFz gases can be introduced into the processing chamber at a flow rate of between about 2 sccm to about 20000 sccm. The processing time may vary depending on the desired thickness of the seasoning layer.

Block 310 provides performing the deposition process in the processing chamber. When the internal components of the processing chamber have been seasoned, arcing is greatly reduced or eliminated within the chamber components. For example, more than 4,000 substrates can be processed without removing the thermal conductive support 214 due to arcing. Furthermore, as discussed above, electrostatic chucking degradation is also reduced after performing the seasoning layer formation process that forms the heat resistivity layer 222. With other approaches, the only way to recover the components after an arcing event is to remove the chamber components, which greatly decrease the chamber uptime and increase the cost of operation.

While the foregoing is directed to embodiments of the present disclosure, other and further embodiments of the disclosure may be devised without departing from the basic scope thereof, and the scope thereof is determined by the claims that follow.

We claim:

1. A processing chamber component, comprising:
a dielectric body having a first surface;
an electrode that is disposed within the dielectric body; and
a high resistivity layer, wherein the high resistivity layer is disposed on the first surface of the dielectric body, wherein the high resistivity layer has an electrical resistivity between about 1×10⁹ and about 1×10¹⁷ ohm-centimeters.

2. The processing chamber component of claim 1, wherein the electrode is less than or equal to 1 millimeter below the first surface of the dielectric body.

3. The processing chamber component of claim 1, further comprising a process kit stack having a top dielectric spacer, a side electrode, and a bottom dielectric spacer.

4. The processing chamber component of claim 1, wherein the high resistivity layer has a thickness between about 1 and about 20 micrometers.

5. The processing chamber component of claim 1, wherein the high resistivity layer has a dielectric constant between about 3 and about 10.

6. The processing chamber component of claim 5, wherein the dielectric constant is between about 3.4 and about 4.0.

7. The processing chamber component of claim 1, wherein the electrical resistivity is about 1×10¹³ ohm centimeters.

8. The processing chamber component of claim 1, wherein the high resistivity layer comprises silicon oxide (SiOₓ).

9. A processing chamber, comprising:
a process kit stack having an inner surface, wherein the inner surface faces a processing region within a chamber body;
a thermal conductive support, wherein the thermal conductive support comprises:
a dielectric body comprising a top surface, wherein the top surface is configured to support a substrate; and
an electrode that is disposed within the dielectric body; and
a high resistivity layer, wherein the high resistivity layer is disposed on the inner surface of the at least one process kit and on the top surface of the dielectric body, wherein the high resistivity layer has an electrical resistivity between 1×10⁹ and 1×10¹⁷ ohm-centimeters.

10. The processing chamber of claim 9, wherein the electrode is less than or equal to 1 millimeter below the top surface of the dielectric body.

11. The processing chamber of claim 9, wherein the process kit stack comprises a top dielectric spacer, a bottom dielectric spacer and a side electrode disposed between the top dielectric spacer and a bottom dielectric spacer.

12. The processing chamber of claim 9, wherein the high resistivity layer has a thickness between about 1 and about 20 micrometers.

13. The processing chamber of claim 9, wherein the high resistivity layer has a dielectric constant between about 3 and about 10.

14. The processing chamber of claim 9, further comprising an edge ring having a bottom surface, wherein the edge ring is disposed on the top surface of the dielectric body and the high resistivity layer is disposed between the top surface of the dielectric body and the bottom surface of the edge ring.

15. A method for fabricating a chamber component for use in a processing environment, comprising:
forming a body of the chamber component;
installing the chamber component into a processing chamber;
depositing a high resistivity layer on the surface of the body in-situ, wherein a pressure between about 50 mTorr and about 20 Torr is applied, a power between about 10 and about 3000 watts is applied, a temperature is between about 50 and about 1100 degrees Celsius, a silicon-containing gas is applied at a gas flow rate between about 2 to about 20000 sccm, an oxygen containing gas is applied at a gas flow rate between about 2 sccm to about 30000 sccm, and inert gases are applied at a flow rate between about 10 sccm to about 20000 sccm; and
performing a deposition process in the processing chamber.

16. The method of claim 15, wherein the high resistivity layer comprises silicon oxide (SiOₓ).

17. The method of claim 15, wherein the chamber component is a thermal conductive support.

18. The method of claim 15, wherein the high resistivity layer has a dielectric thickness between about 1 and about 20 micrometers.

19. The method of claim 15, wherein the high resistivity layer has a dielectric constant between about 3 and about 10.

20. The method of claim 15, wherein an electrical resistivity of the high resistivity layer is between about 1×10⁹ and about 1×10¹⁷ ohm centimeters.
